(19) United States
(12) Patent Application Publication
(10) Pub. No.: US 2024/0377479 A1
(43) Pub. Date: Nov. 14, 2024

(54) Electrical Outlet Diagnostic Device

(71) Applicant: Milwaukee Electric Tool Corporation, Brookfield, WI (US)

(72) Inventors: Aaron C. Grode, Brookfield, WI (US); Troy A. Marks, Wauwatosa, WI (US)

(21) Appl. No.: 18/654,751

(22) Filed: May 3, 2024

Related U.S. Application Data
(60) Provisional application No. 63/501,033, filed on May 9, 2023.

(51) Int. Cl. G01R 31/69; G01R 31/327

(52) U.S. Cl. CPC G01R 31/69; G01R 31/3274

(57) ABSTRACT

Various embodiments of an electrical outlet diagnostic devices are provided. In some embodiments, the electrical outlet diagnostic device is a circuit breaker finder including a transmitter device having both two-prong and three-prong electrical outlet interfaces and/or an LCD digital display. In other embodiments, the electrical outlet diagnostic device is a multi-purpose electrical outlet tester including electrical outlet interfaces configured to electrically couple the device to two-prong, three-prong, USB-A, USB-B, and/or USB-C outlet configurations.

### CROSS-REFERENCE TO RELATED PATENT APPLICATION

This application claims the benefit of and priority to U.S. Application No. 63/501,033, filed May 9, 2023, the contents of which are incorporated herein in its entirety.

### BACKGROUND OF THE INVENTION

The present disclosure is directed generally to the field of tools. The present disclosure relates specifically to electrical outlet diagnostic devices, such as a circuit breaker finder and/or an outlet tester.

### SUMMARY OF THE INVENTION

One embodiment of the invention relates to an electrical outlet diagnostic device having a transmitter device configured to electrically couple to an electrical outlet and transmit an electrical signal. The transmitter device includes a housing, a user interface, a first electrical outlet interface and a second electrical outlet interface. The first electrical outlet interface includes a first conductive pin, a second conductive pin, and a ground pin. The second electrical outlet interface, distinct and separate from the first electrical outlet interface, includes a third conductive pin and a fourth conductive pin. The electrical outlet diagnostic device includes a receiver device configured to detect electromagnetic signals. The receiver device includes a gripping portion, a sensor, and an indicator. When the sensor of the receiver device detects an electromagnetic signal corresponding to the electrical signal, the indicator provides an indication.

Another embodiment of the invention relates to an electrical outlet diagnostic device having a circuit breaker finder transmitter configured to electrically couple to an electrical outlet and transmit an electrical signal. The transmitter includes a housing, a user interface including a digital display, and a first electrical outlet interface. The first electrical outlet interface includes a first conductive pin and a second conductive pin. The electrical outlet diagnostic device includes a circuit breaker finder receiver configured to detect electromagnetic signals. The receiver includes a gripping portion, a sensor, and an indicator. When the sensor of the receiver detects an electromagnetic signal corresponding to the electrical signal, the indicator provides an indication.

Another embodiment of the invention relates to an electrical outlet diagnostic device including a housing, a user interface, and a plurality of electrical outlet interfaces. The plurality of electrical outlet interfaces includes a first electrical outlet interface configured to couple to an electrical receptacle and including a first conductive pin and a second conductive pin, and a second electrical outlet interface that includes a USB port. The electrical outlet diagnostic device is configured to measure voltage and amperage of an electrical outlet electrically coupled to one of the plurality of electrical outlet interfaces.

Various embodiments of the invention relate to electrical outlet diagnostic devices with various features to improve functionality and/or case of use. In some embodiments, the electrical diagnostic device includes both a two-prong outlet interface and a three-prong outlet interface. In a specific embodiment, the electrical outlet diagnostic device is a circuit breaker finder including a transmitter and a receiver, and in such embodiments, the transmitter includes both a two-prong outlet interface and a three-prong outlet interface. In a more specific embodiment, the circuit breaker finder transmitter includes an LCD display.

In another specific embodiment, the electrical outlet diagnostic device is an outlet tester device configured for testing a variety of outlets including a two-prong outlet interface, a three-prong outlet interface, a USB-A outlet interface and a USB-C outlet interface. In specific embodiments, the outlet tester includes a ground fault circuit interrupter tester.

Additional features and advantages will be set forth in the detailed description which follows, and, in part, will be readily apparent to those skilled in the art from the description or recognized by practicing the embodiments as described in the written description included, as well as the appended drawings. It is to be understood that both the foregoing general description and the following detailed description are exemplary.

The accompanying drawings are included to provide further understanding and are incorporated in and constitute a part of this specification. The drawings illustrate one or more embodiments and, together with the description, serve to explain principles and operation of the various embodiments.

### BRIEF DESCRIPTION OF THE DRAWINGS

This application will become more fully understood from the following detailed description, taken in conjunction with the accompanying figures, wherein like reference numerals refer to like elements in which:

FIG. 1 is a side view of a circuit breaker finder transmitter device, according to an exemplary embodiment.

FIG. 2 is a perspective view of a circuit breaker finder receiver device, according to an exemplary embodiment.

FIG. 3a is a perspective view of the circuit breaker finder transmitter device of FIG. 1 with a two-prong interface in an extended position, according to an exemplary embodiment.

FIG. 3b is a perspective view of the circuit breaker finder transmitter device of FIG. 1 with a two-prong interface in a stowed position, according to an exemplary embodiment.

FIG. 4 is a side view of a circuit breaker finder transmitter device, according to an exemplary embodiment.

FIG. 5 is a perspective view of the circuit breaker finder transmitter device of FIG. 4 with a two-prong interface in an extended position, according to an exemplary embodiment.

FIG. 6 is a perspective view of a multi-purpose outlet tester, according to an exemplary embodiment.

### DETAILED DESCRIPTION

Referring generally to the figures, various embodiments of electrical outlet diagnostic devices with various features to improve functionality and/or ease of use are shown. In some embodiments, the electrical diagnostic device includes both a two-prong outlet interface and a three-prong outlet interface. Various embodiments of the electrical diagnostic device include one or more USB ports configured to interface with USB outlets. Unlike some conventional electrical outlet diagnostic tools that only include a single outlet interface, the electrical outlet diagnostic devices described herein are configured to interface with a variety of outlets having a variety of outlet configurations.

Referring to FIG. 1, a circuit breaker finder transmitter 10 is shown, according to an exemplary embodiment. Transmitter 10 includes a housing 12 having grip portions 14 on opposing sides of housing 12. Transmitter 10 further includes a plurality of conductive prongs configured to interface with an electrical receptacle. The plurality of conductive prongs includes a first pin 16 and a second pin 18. In a specific embodiment, the plurality of conductive prongs further includes a ground pin 20. The combination of first pin 16, second pin 18, and ground pin 20 are configured to interface with and connect to a standard 3-pin electrical receptacle, or ground receptacle. In a specific embodiment, the combination of first pin 16, second pin 18, and ground pin 20 form a National Electrical Manufacturer's Association (NEMA) 5-15 plug configuration. First pin 16, second pin 18, and ground pin 20 form a first electrical outlet interface that extends outward from a top surface of housing 12.

As shown in FIG. 1, transmitter 10 includes a user interface 22. In some embodiments, user interface 22 includes a digital screen 24, such as an LCD screen. User interface 22 also includes a first actuator 26 and a second actuator 28. First actuator 26 and second actuator 28 are configured to receive inputs from a user and control operation of transmitter 10, such as activating transmitter 10 or resetting transmitter 10. Transmitter 10 includes a first indicator 30, and a second indicator 32. In a specific embodiment, first indicator 30 and/or second indicator 32 are light emitting devices, such as LEDs and provide indications to regarding the status of transmitter 10 and/or an electrical circuit that transmitter 10 is electrically coupled to.

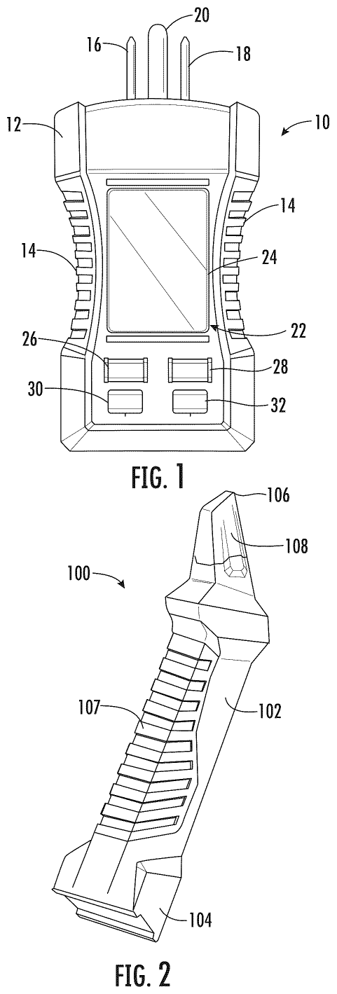

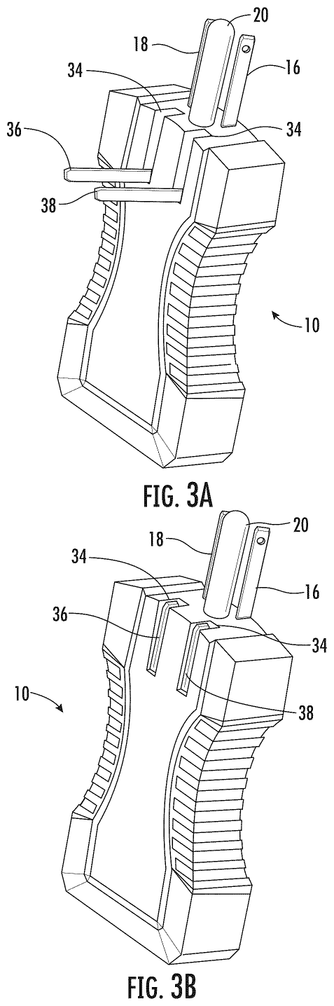

Referring to FIG. 2, a circuit breaker finder receiver 100 is shown, according to an exemplary embodiment. Receiver 100 includes a body 102 having a first end 104 and a second end 106 opposite first end 104. Body 102 includes a gripping portion 107 between first end 104 and second end 106 configured to receive the hand of a user. Receiver 100 further includes a sensor 108 located near second end 106. Receiver 100 includes an indicator within and/or on body 102. In various embodiments, the indicator produces a sound and/or illuminates when sensor 108 detects an electromagnetic signal.

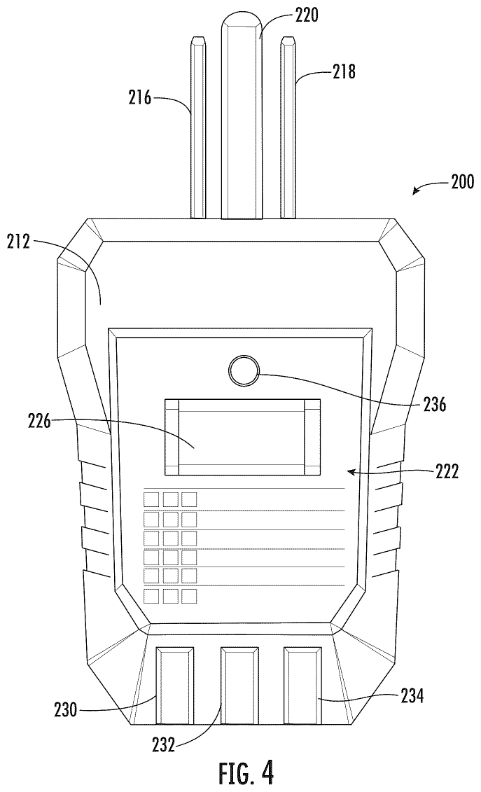

As shown in FIG. 3A, transmitter 10 further includes a plurality of pin slots 34, a third pin 36, and a fourth pin 38. Third pin 36 and fourth pin 38 are pivotably coupled to housing 12. As shown in FIG. 3B, third pin 36 and fourth pin 38 can rotate to be retained within pin slots 34. As such, third pin 36 and fourth pin 38 can actuate between an extended coupling position, shown in FIG. 3A, and a stowed position, shown in FIG. 3B. When in the extended coupling position, the combination of third pin 36 and fourth pin 38 are configured to interface with and connect to a standard 2-pin electrical receptacle, or ground receptacle. As such, third pin 36 and fourth pin 38 form a second electrical outlet interface that extends outward from a back surface of housing 12, when in the extended coupling position. The second electrical outlet interface is distinct and separate from the first electrical outlet interface.

In a specific embodiment, the combination of third pin 36 and fourth pin 38 form a NEMA 1-15 plug configuration. Applicant has found it beneficial to provide a circuit breaker finder transmitter having multiple sets of conductive prongs configured to couple with a standard 3-pin electrical receptacle and a standard 2-pin electrical receptacle, respectively (i.e., in both a NEMA 5-15 plug configuration and a NEMA 1-15 plug configuration), because the circuit breaker finder transmitter can be coupled to electrical receptacles having various different configurations without requiring a separate transmitter device for each different configuration.

Transmitter 10 is configured to electrically couple to an electrical receptacle having circuit with a circuit breaker. Transmitter 10 includes a circuit within housing 12. The circuit within housing 12 is configured to send an electrical signal through the electrical receptacle to the circuit breaker via the plurality of conductive prongs. While transmitter 10 transmits a signal to the circuit breaker, a user can move receiver 100 along a circuit breaker panel containing a plurality of circuit breakers including the circuit breaker electrically coupled to transmitter 10 such that sensor 108 is in close proximity to (e.g., within several inches) the individual circuit breakers. As sensor 108 passes close to the circuit breaker electrically coupled to transmitter 10, sensor 108 detects an electromagnetic field corresponding to the electrical signal produced by transmitter 10, and receiver 100 produces indications (e.g., sounds and/or lights) that increase in intensity and/or frequency of repetitions as the intensity of the detected signal increase (i.e., as sensor 108 is positioned closer to the circuit breaker transmitting the signal from transmitter 10). As such, a user can determine which circuit breaker in a circuit breaker panel is electrically coupled to transmitter 10 by placing sensor 108 near each circuit breaker and observing which circuit breaker causes receiver 100 to produce the most frequent or intense indications. In specific embodiments, transmitter 10 is configured to automatically calibrate.

Referring to FIG. 4, a front-side view of a circuit breaker finder transmitter 200 is shown, according to an exemplary embodiment. Transmitter 200 is substantially similar to transmitter 10, except for the differences described. Transmitter 200 includes a housing 212 and a first pin 216, a second pin 218, and a ground pin 220 extending out of a top side of housing 212. The combination of first pin 216, second pin 218, and ground pin 220 are configured to interface with and connect to a standard 3-pin electrical receptacle, or ground receptacle.

Transmitter 200 further includes a user interface 222 including an actuator 226, a first indicator 230, a second indicator 232, a third indicator 234, and a fourth indicator 236. In a specific embodiment, each of first indicator 230, second indicator 232, third indicator 234, and fourth indicator 236 are LEDs. First indicator 230, second indicator 232, and third indicator 234 are located along a bottom edge of housing 212 such that a portion of each indicator is located on a front side of housing 212 and a portion of each indicator is located on a bottom side of housing 212. In some embodiments, transmitter 200 is activated by pressing actuator 226 toward and/or into housing 212. Fourth indicator 236 is configured to provide an indication, such as by emitting light, when transmitter 200 is activated. First indicator 230, second indicator 232, and third indicator 234 are configured to provide indications, such as by emitting light, related to the status of a circuit to which transmitter 200 is electrically coupled and/or related to the status and operation of transmitter 200.

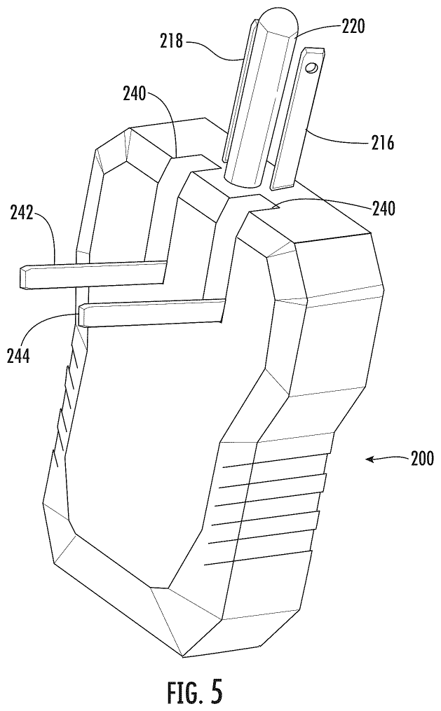

As shown in FIG. 5, transmitter 200 includes a plurality of pin slots 240, a third pin 242, and a fourth pin 244. Similar to transmitter 10, third pin 242 and fourth pin 244 can rotate between an extended coupling position, shown in FIG. 5, and a stowed position in which third pin 242 and fourth pin 244 are retained within pin slots 240. When in the extended coupling position, the combination of third pin 242 and fourth pin 244 are configured to interface with and connect to a standard 2-pin electrical receptacle, or ground receptacle. In a specific embodiment, the combination of third pin 36 and fourth pin 38 form a NEMA 1-15 plug configuration. As such, transmitter 200 includes sets of conductive prongs in both a NEMA 5-15 plug configuration and a NEMA 1-15 plug configuration.

Transmitter 200 is configured to be used in combination with receiver 100 to find circuit breakers in the same manner described above with respect to transmitter 10.

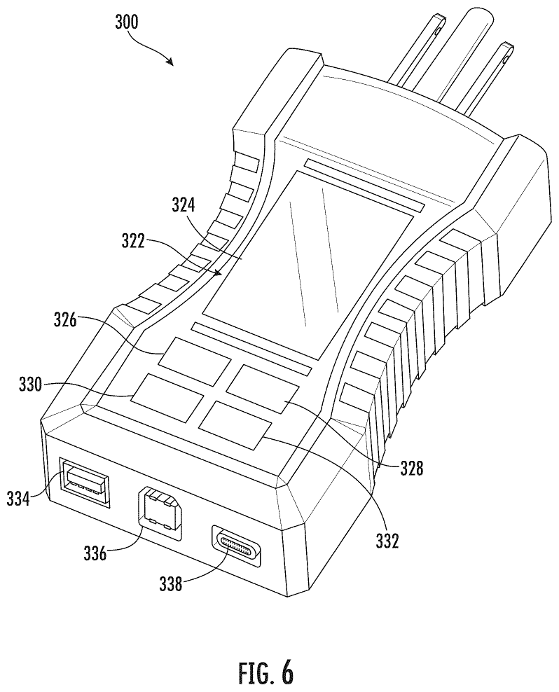

Referring to FIG. 6, a perspective view of an outlet tester 300 is shown, according to an exemplary embodiment. Outlet tester 300 is substantially similar to transmitter 10, except for the differences described. Outlet tester 300 includes a user interface 322 having a digital display 324, such as an LCD screen, a first actuator 326, a second actuator 328, a first indicator 330, and a second indicator 332. Similar to transmitter 10, outlet tester 300 includes sets of conductive prongs in both a NEMA 5-15 plug configuration and a NEMA 1-15 plug configuration such that outlet tester 300 can electrically couple to both three-prong and two-prong electrical receptacles.

As shown in FIG. 6, outlet tester 300 includes a plurality of USB ports including a USB-A port 334. In a specific embodiment, outlet tester 300 further includes a USB-B port 336 and/or a USB-C port 338.

Outlet tester 300 is a multi-purpose electrical outlet diagnostic device. Outlet tester 300 is configured to measure voltage and amperage of an outlet and/or is configured to test functioning of a ground-fault circuit interrupter (GFCI). In specific embodiments, outlet tester 300 is configured to electrically couple to and test a variety of electrical outlet configurations including two-prong electrical receptacles, three-prong electrical receptacle, USB-A outlets, USB-B outlets, and/or USB-C outlets. In specific embodiments, outlet tester 300 includes a ground fault circuit interrupter tester. Digital display 324 is configured to display information related to the outlet being tested, such as voltage, amperage, and/or status of the outlet's GFCI. Applicant has found the multi-purpose tester functionality described above beneficial because it provides for a single device capable of testing the operation of wide variety of outlet configurations and that is also capable of testing for proper GFCI functioning, rather than requiring multiple devices for each outlet configuration.

It should be understood that the figures illustrate the exemplary embodiments in detail, and it should be understood that the present application is not limited to the details or methodology set forth in the description or illustrated in the figures. It should also be understood that the terminology is for description purposes only and should not be regarded as limiting.

Further modifications and alternative embodiments of various aspects of the disclosure will be apparent to those skilled in the art in view of this description. Accordingly, this description is to be construed as illustrative only. The construction and arrangements, shown in the various exemplary embodiments, are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Some elements shown as integrally formed may be constructed of multiple parts or elements, the position of elements may be reversed or otherwise varied, and the nature or number of discrete elements or positions may be altered or varied. The order or sequence of any process, logical algorithm, or method steps may be varied or re-sequenced according to alternative embodiments. Other substitutions, modifications, changes and omissions may also be made in the design, operating conditions and arrangement of the various exemplary embodiments without departing from the scope of the present disclosure.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred. In addition, as used herein, the article “a” is intended to include one or more component or element, and is not intended to be construed as meaning only one. As used herein, “rigidly coupled” refers to two components being coupled in a manner such that the components move together in a fixed positional relationship when acted upon by a force.

Various embodiments of the disclosure relate to any combination of any of the features, and any such combination of features may be claimed in this or future applications. Any of the features, elements or components of any of the exemplary embodiments discussed above may be utilized alone or in combination with any of the features, elements or components of any of the other embodiments discussed above.

For purposes of this disclosure, the term “coupled” means the joining of two components directly or indirectly to one another. Such joining may be stationary in nature or movable in nature. Such joining may be achieved with the two members and any additional intermediate members being integrally formed as a single unitary body with one another or with the two members or the two members and any additional member being attached to one another. Such joining may be permanent in nature or alternatively may be removable or releasable in nature.

While the current application recites particular combinations of features in the claims appended hereto, various embodiments of the invention relate to any combination of any of the features described herein whether or not such combination is currently claimed, and any such combination of features may be claimed in this or future applications. Any of the features, elements, or components of any of the exemplary embodiments discussed above may be used alone or in combination with any of the features, elements, or components of any of the other embodiments discussed above.

In various exemplary embodiments, the relative dimensions, including angles, lengths and radii, as shown in the Figures are to scale. Actual measurements of the Figures will disclose relative dimensions, angles and proportions of the various exemplary embodiments. Various exemplary embodiments extend to various ranges around the absolute and relative dimensions, angles and proportions that may be determined from the Figures. Various exemplary embodiments include any combination of one or more relative dimensions or angles that may be determined from the Figures. Further, actual dimensions not expressly set out in this description can be determined by using the ratios of dimensions measured in the Figures in combination with the express dimensions set out in this description.

What is claimed is:

1. An electrical outlet diagnostic device, comprising:
a transmitter device configured to electrically couple to an electrical outlet and transmit an electrical signal, the transmitter device comprising:
a housing;
a user interface;
a first electrical outlet interface comprising a first conductive pin, a second conductive pin, and a ground pin;
a second electrical outlet interface, distinct and separate from the first electrical outlet interface, the second electrical outlet interface comprising a third conductive pin and a fourth conductive pin;
a receiver device configured to detect electromagnetic signals, the receiver device comprising:
a gripping portion;
a sensor; and
an indicator;
wherein when the sensor of the receiver device detects an electromagnetic signal corresponding to the electrical signal, the indicator provides an indication.

2. The electrical outlet diagnostic device of claim 1, wherein the first electrical outlet interface is configured to electrically couple to a three-prong electrical receptacle and the second electrical outlet interface is configured to electrically couple to a two-prong electrical receptacle; and
wherein the first electrical outlet interface extends outward from a first face of the housing and the second electrical outlet interface extends outward from a second face of the housing.

3. The electrical outlet diagnostic device of claim 2, wherein the pins of the first electrical outlet interface are in a NEMA 5-15 plug configuration and the pins of the second electrical outlet interface are in a NEMA 1-15 plug configuration.

4. The electrical outlet diagnostic device of claim 1, wherein the user interface of the transmitter device comprises an LCD screen.

5. The electrical outlet diagnostic device of claim 4, wherein the user interface of the transmitter device further comprises a plurality of LED indicators and a plurality of actuators.

6. The electrical outlet diagnostic device of claim 1, wherein the user interface of the transmitter comprises a plurality of LED indicators, each LED indicator being located on an edge of the housing such that a portion of each LED indicator extends along a front surface of the housing and a portion of each LED indicator extends along a bottom surface of the housing.

7. The electrical outlet diagnostic device of claim 1, wherein the indication provided by the receiver device is a sound and/or emitted light that increases in intensity as an intensity of the electromagnetic signal detected by the sensor increases.

8. The electrical outlet diagnostic device of claim 1, wherein the indication provided by the receiver device is a repeated sound and/or repeated emitted light that increases in frequency of repetitions as an intensity of the electromagnetic signal detected by the sensor increases.

9. An electrical outlet diagnostic device, comprising:
a circuit breaker finder transmitter configured to electrically couple to an electrical outlet and transmit an electrical signal, the transmitter comprising:
a housing;
a user interface comprising a digital display;
a first electrical outlet interface comprising a first conductive pin and a second conductive pin;
a circuit breaker finder receiver configured to detect electromagnetic signals, the receiver comprising:
a gripping portion;
a sensor; and
an indicator;
wherein when the sensor of the receiver device detects an electromagnetic signal corresponding to the electrical signal, the indicator provides an indication.

10. The electrical outlet diagnostic device of claim 9, wherein the digital display is an LCD screen.

11. The electrical outlet diagnostic device of claim 10, wherein the user interface of the transmitter further comprises a plurality of LED indicators and a plurality of actuators.

12. The electrical outlet diagnostic device of claim 9, wherein the first electrical outlet interface further comprises a ground pin and is configured to electrically couple to a three-prong electrical receptacle.

13. The electrical outlet diagnostic device of claim 12, wherein the transmitter further comprises a second electrical outlet interface, distinct and separate from the first electrical outlet interface, the second electrical outlet interface comprising a third conductive pin and a fourth conductive pin, the second electrical outlet interface being configured to electrically couple to a two-prong electrical receptacle; and
wherein the first electrical outlet interface extends outward from a first face of the housing and the second electrical outlet interface extends outward from a second face of the housing.

14. The electrical outlet diagnostic device of claim 9, wherein the indication provided by the receiver is a repeated sound and/or repeated emitted light that increases in frequency of repetitions as an intensity of the electromagnetic signal detected by the sensor increases.

15. An electrical outlet diagnostic device, comprising:
a housing;
a user interface;
a plurality of electrical outlet interfaces comprising:
a first electrical outlet interface configured to couple to an electrical receptacle and comprising a first conductive pin and a second conductive pin;
a second electrical outlet interface comprising a USB port;
wherein the electrical outlet diagnostic device is configured to measure voltage and amperage of an electrical outlet electrically coupled to one of the plurality of electrical outlet interfaces.

16. The electrical outlet diagnostic device of claim 15, wherein the USB port of the second electrical outlet interface is a USB-A port; and
wherein the plurality of electrical outlet interfaces further comprises a third electrical outlet interface comprising a USB-C port.

17. The electrical outlet diagnostic device of claim 16, wherein the plurality of electrical outlet interfaces further comprises a fourth electrical outlet interface comprising a USB-B port.

18. The electrical outlet diagnostic device of claim 17, wherein the plurality of electrical outlet interfaces further comprises a fifth electrical outlet interface, distinct and separate from the first electrical outlet interface, the fifth electrical outlet interface comprising a third conductive pin, a fourth conductive pin, and a ground pin such that the first electrical outlet interface is configured to electrically couple to a two-prong electrical receptacle and the fifth electrical outlet interface is configured to electrically couple to a three-prong electrical receptacle.

19. The electrical outlet diagnostic device of claim 15, wherein the user interface comprises an LCD screen.

20. The electrical outlet diagnostic device of claim 15, wherein the electrical outlet diagnostic device is configured to test the functionality of a ground fault circuit interrupter connected to the electrical outlet electrically coupled to one of the plurality of electrical outlet interfaces.
